(19) United States
(12) Patent Application Publication
(10) Pub. No.: US 2006/0086975 A1
(43) Pub. Date: Apr. 27, 2006

(54) Device junction structure

(75) Inventor: Jhon-Jhy Liaw, Hsin-Chu (TW)

Correspondence Address: TUNG & ASSOCIATES;Suite 120, 838 W. Long Lake Road, Bloomfield Hills, MI, 48302, US

(73) Assignee: Taiwan Semiconductor Manufacturing Co., Ltd.

(21) Appl. No.: 10/971,326

(22) Filed: Oct. 22, 2004

(51) Int. Cl. H01L 21/336

(52) U.S. Cl. 257/344

(57) ABSTRACT

A semiconductor device includes a gate structure having a plurality of gate layers, which are layered upon a gate dielectric. A pair of thin spacers is formed on corresponding sidewalls of the gate structure. Each thin spacer is at most 25 nanometers (nm) wide. Length of the gate structure is at most 40 nm. Source and drain regions of the device are self aligned and disposed adjacently below on either side of each thin spacer and a corresponding edge of the gate structure. The source and drain regions include impurity concentrations-of a selectable type to form a smooth junction profile under each thin spacer and the corresponding edge of the gate structure.

### BACKGROUND OF THE INVENTION

The present invention relates generally to integrated circuits and semiconductor devices, and, more particularly, to an improved process and device junction structure for fabricating semiconductor devices having nanometer (nm) geometries.

Reduced geometry integrated circuit (“IC”) chip designs are being adopted to increase the density of devices within integrated circuits, thereby increasing performance and decreasing the cost of the ICs. Modem IC memory chips, such as dynamic random access memory (“DRAM”), static random access memory (“SRAM”), and read only memory (“ROM”), are examples of chips having increasingly higher densities and lower costs. Increases in chip density are primarily accomplished by scaling techniques to reduce dimensions while improving performance. That is, by forming smaller structures within devices, and by reducing the separation between devices or between the structures that make up the devices.

The ability to improve performance consistently while decreasing power consumption has made Complementary Metal Oxide Semiconductor (CMOS) architecture a preferred choice for integrated circuits. The scaling of the CMOS transistor has been the primary factor driving improvements in microprocessor performance. Commercially available semiconductor devices such as Metal Oxide Semiconductor Field Effect Transistor (MOSFET) have been scaled to the point where the channel length from source to drain is below 40 nm.

FIG. 1 shows a portion of a prior art transistor 100 formation on a substrate 110. The transistor device 100, which is formed on the substrate 110, includes an active area 105, such as a p-well or an n-well, and a field oxide region 107 for isolation. Depicted is a gate 120 structure comprising a metal silicide layer 122 and cap 1-24 overlying a gate dielectric 114. In some gate structures, a polysilicon layer (not shown) may also be included. Thicker spacers 126 are used for electrical isolation and for keeping heavy implant dopants away from directly under contact for the gate 120. Source and drain regions (130 and 140 respectively) are then formed self-aligned with and adjacent to the gate 120 by implanting of high-concentration impurities into the surface of the substrate 110.

As channel 125 length becomes shorter the electric field in the channel region increases thereby resulting in higher substrate current and increased hot carrier problems primarily due to a tendency to become trapped in the gate dielectric region. One well known method that has been employed to partially overcome these problems and increase device reliability/performance of these devices involves adding lightly doped drain (LDD) regions 150 and 152 between the channel 125 region and each of the source 130 and drain 140 region. The LDD regions 150 and 152 are designed to minimize hot carrier effects since the reduced doping gradient between drain 140 and channel 125 lowers electric field in the channel 125 in the vicinity of the drain 140. Depicted in FIG. 1 is the LDD regions 150 and 152 and deep source/drain (S/D) regions 130 and 140 having a non-smooth junction profile 170 under edge of gate 120 and spacers 126. Width of thicker spacers 126 generally determines length of the LDD regions 150 and 152.

The non-smooth profile 170 is formed by double off-set regions whereby the source/drain 130 and 140 regions and LDD region 150 include high impurity concentrations and low impurity concentrations respectively. The primary objective of the LDD regions 150 and 152 is to offset the high concentration of the electric field around the drain 140 region.

In nm generation devices, the transistor gate pitches continue to shrink. Tightened space requirements and shorter channel length typically require thin spacers and shallow S/D junction depth. Use of traditional scaling techniques to obtain further reductions in geometries may be difficult due to increased short channel effects and reduced device performance. Formation of LDD region 150 and 152 may become a difficult process when thickness of spacers 126 is below 250 angstroms (A) and channel 125 length is shorter than 40 nm.

Thus, a need exists for an improved process and device junction structure for fabricating semiconductor devices deploying nanometer geometries and having reduced short channel effects. It would be desirable to fabricate an improved semiconductor device having reduced size, improved performance, lower cost and more reliability. Additionally, it would be desirable for the improved device to have more robust hot carrier lifetime and higher junction breakdown voltage.

### SUMMARY OF THE INVENTION

The problems outlined above are addressed in a large part by an improved process and device junction structure for fabricating semiconductor devices deploying nanometer geometries to reduce short channel effects, as described herein. According to one form of the invention, a semiconductor device includes a gate structure having a plurality of gate layers, which are layered upon a gate dielectric. A pair of thin spacers is formed on corresponding sidewalls of the gate structure. Each thin spacer is at most 25 nanometers (nm) wide. Length of the gate structure is at most 40 nm. Source and drain regions of the device are self aligned and disposed adjacently below on either side of each thin spacer and a corresponding edge of the gate structure. The source and drain regions include impurity concentrations of a selectable type to form a smooth junction profile under each thin spacer and the corresponding edge of the gate structure.

According to another aspect of the invention, a device structure for first and second devices formed on a substrate includes the first device having a first gate structure, which includes a plurality of first gate layers layered upon a first gate dielectric. A plurality of first thin spacers is formed on corresponding sidewalls of the first gate structure. First source and first drain regions of the first device are self aligned and disposed adjacently below on either side of each first thin spacer and a corresponding edge of the first gate structure. The second device includes a second gate structure, which includes a plurality of second gate layers layered upon a second gate dielectric. A plurality of second thick spacers is formed on the corresponding sidewalls of the second gate structure. A difference between each of the first thin spacers and each of the second thick spacers is selectable to exceed a predefined width. Second source and second drain regions of the second device are self aligned and disposed adjacently below on either side of each second thick spacer and a corresponding edge of the second gate structure.

Other forms, as well as objects and advantages of the invention will become apparent upon reading the following detailed description and upon reference to the accompanying drawings.

### BRIEF DESCRIPTION OF THE DRAWINGS

Novel features believed characteristic of the invention are set forth in the appended claims. The invention itself, however, as well as a preferred mode of use, various objectives and advantages thereof, will best be understood by reference to the following detailed description of an illustrative embodiment when read in conjunction with the accompanying drawings, wherein:

FIG. 1 is an illustrative layout diagram of a prior art transistor formation on a substrate, described herein above;

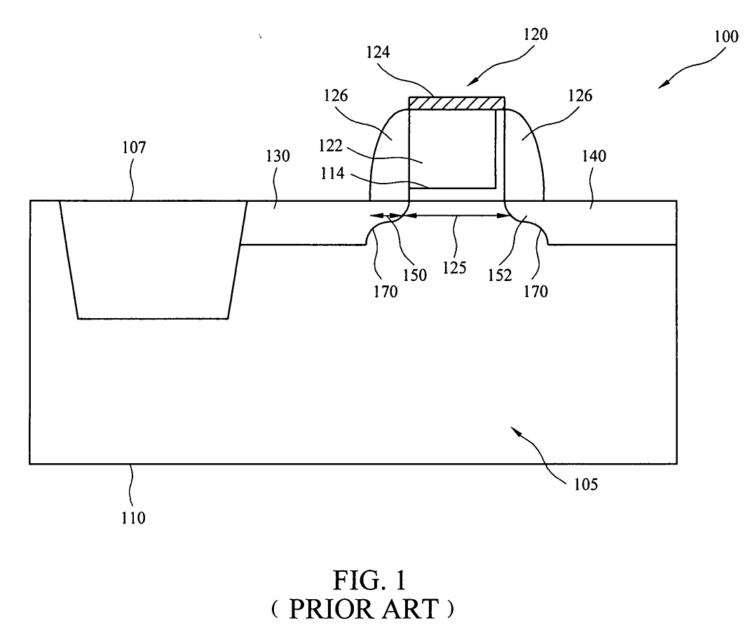

FIG. 2 is an illustrative layout diagram of a semiconductor device having an improved device junction structure, according to an embodiment;

FIG. 3A is an illustrative layout diagram of first and second devices, each having an improved device junction structure formed on a semiconductor wafer, according to an embodiment;

FIG. 3B is another illustrative layout diagram of first and second devices, each having an improved device junction structure formed on a semiconductor wafer, according to an embodiment;

FIG. 4A is an exemplary flow chart illustrating a method for forming a CMOS device on a semiconductor wafer having an improved device junction structure, according to an embodiment; and

FIG. 4B is an exemplary flow chart illustrating additional details of forming core CMOS S/D regions described in FIG. 4A, according to one embodiment.

### DETAILED DESCRIPTION OF AN EMBODIMENT

While the invention is susceptible to various modifications and alternative forms, specific embodiments thereof are shown by way of example in the drawings and will be described herein in detail. It should be understood, however, that the drawings and detailed description thereto are not intended to limit the invention to the particular form disclosed, but on the contrary, the intention is to cover all modifications, equivalents and alternatives falling within the spirit and scope of the present invention as defined by the appended claims.

Elements, which appear in more than one figure herein, are numbered alike in the various figures. The present invention describes an improved process and device junction structure for fabricating semiconductor devices having nanometer (nm) geometries. According to one form of the invention, a semiconductor device includes a gate structure having a plurality of gate layers, which are layered upon a gate dielectric. A pair of thin spacers is formed on corresponding sidewalls of the gate structure. Each thin spacer is at most 25 nanometers (nm) wide. Length of the gate structure is at most 40 nm. Source and drain regions of the device are self aligned and disposed adjacently below on either side of each thin spacer and a corresponding edge of the gate structure. The source and drain regions include impurity concentrations of a selectable type to form a smooth junction profile under each thin spacer and the corresponding edge of the gate structure.

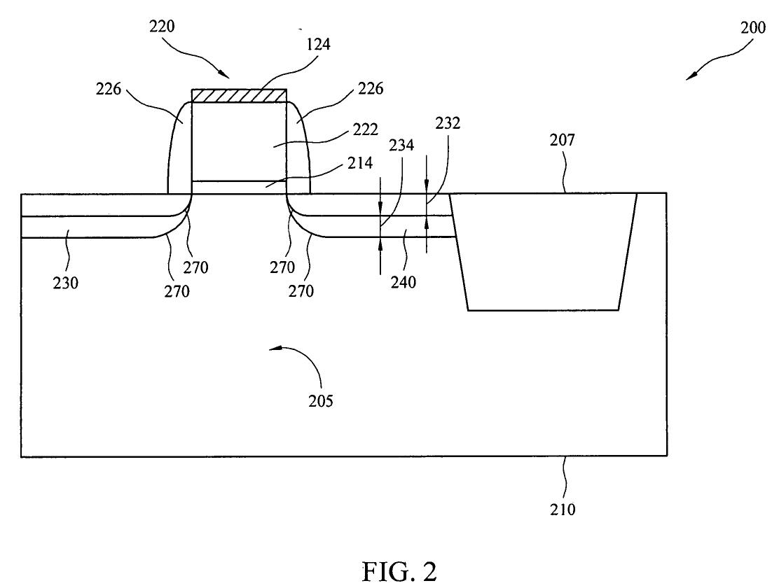

FIG. 2 is an illustrative layout diagram of a semiconductor device 200 having an improved device junction structure, according to an embodiment. In one embodiment, the device 200 is a CMOS device. In one embodiment, the improved device structure is included in a core device having a thinner gate dielectric. The device 200, which is formed on the substrate 210, includes an active area 205, such as a p-well or an n-well, and a field oxide region 207 for isolation. A gate 220 structure includes a metal silicide layer 222 and cap 224 overlying a gate dielectric 214. In one embodiment, the gate dielectric 214 has a thickness that is less than 16 A. In some gate structures, a polysilicon layer (not shown) may also be included. In one embodiment, length of the gate 220 is less than 40 nm and thickness of the gate 220 structure is less than 1000 A. Pair of thin spacers 226 is used for electrical isolation and for keeping heavy implant dopants away from directly under contact for the gate 220.

Source and drain regions (230 and 240 respectively) are then formed self-aligned with and adjacent to the gate 220 by LDD only or S/D only process. That is, they are formed by:

Step A)—implanting of high-concentration impurities into the surface of the substrate 210 to a depth 232; or

Step B)—implanting of lower-concentration impurities into the surface of the substrate 210 to a depth 234, where depth 234 is greater than depth 232 by a predefined amount. In one embodiment, the depth 234 is less than 35 nm.

In one embodiment, the S/D junction implant process used to fabricate device 200 deploys a multiple implant process for improved short channel effect and junction leakage. To alleviate short channel effects such as punch-through, a high concentration impurity having a shallow junction profile is implanted, as described in Step A) above. For reduction injunction leakage and gate overlay, a lower concentration impurity having a deeper junction profile is deployed, as described in Step B) above. Thus, device 200 exhibits more robust hot carrier lifetime and higher junction breakdown voltage.

In one embodiment, device 200 is advantageously fabricated without deploying LDD process thereby simplifying the manufacturing process for nm geometry based devices. The new S/D junction structure for device 200 requires two lithography steps, namely NMOS S/D and PMOS S/D, compared to the conventional process requiring four lithography steps of NMOS S/D, PMOS S/D, NMOS LDD and PMOS LDD.

In the depicted embodiment, the source/drain (S/D) regions 230 and 240 are shown having a smooth junction profile 270 under edge of gate 220 and thin spacers 226. In one embodiment, width of thin spacers 226 is less than 25 nm. The profile 270 is smooth compared to profile 170 since profile 270 does not include any double off-set regions having high impurity concentrations and low impurity concentrations.

In one embodiment, each thin spacer included in the plurality of thin spacers 226 is formed by a material including silicon oxynitride (SiON), silicon nitride (Si3N4), low pressure tetra-ethoxysilane (LPTEOS), high temperature oxide (HTO), furnace oxide, Hf content oxide, Ta content oxide, Al content oxide, high K dielectric where K is greater than 5, oxygen content dielectric, nitrogen content dielectric or a combination thereof.

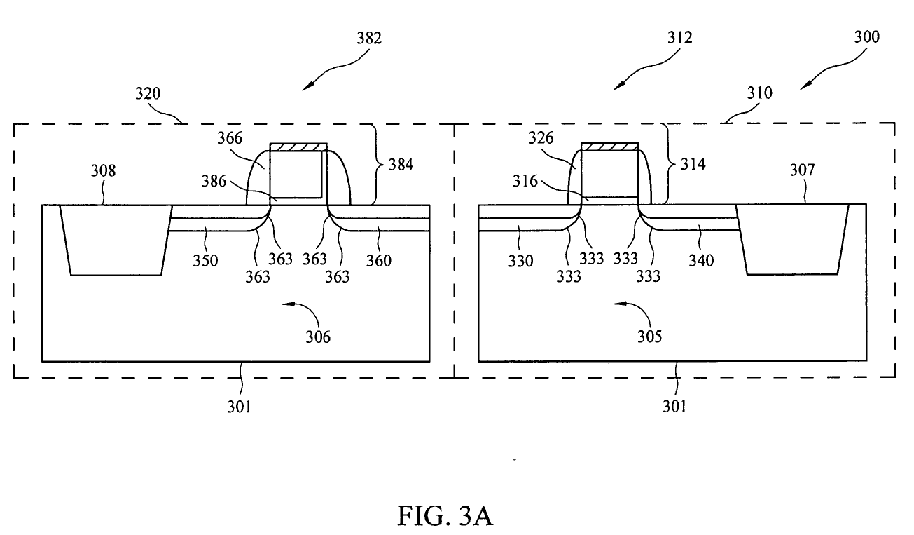

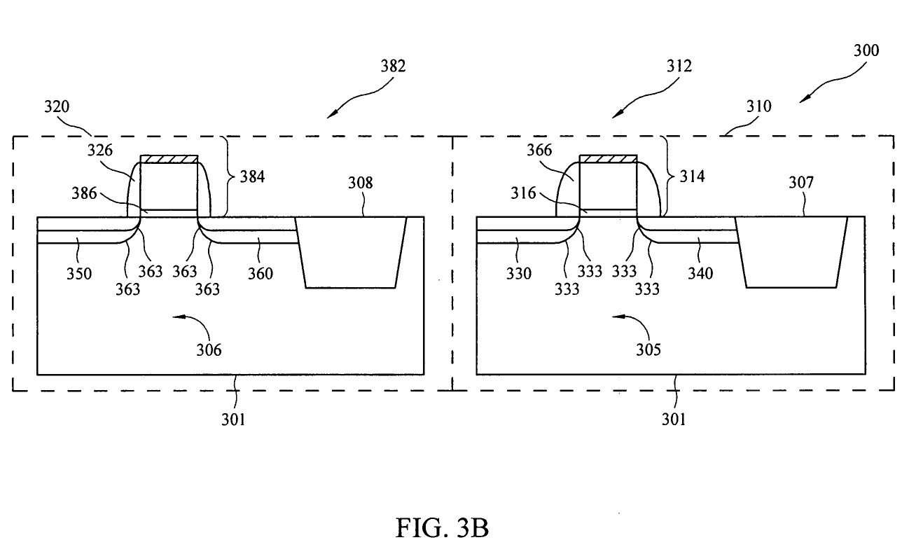

FIG. 3A is an illustrative layout diagram of first and second devices 310 and 320 each having an improved device junction structure formed on a substrate, according to an embodiment. In one embodiment, the first and second devices 310 and 320 are CMOS devices formed on a single chip. In one embodiment, the first device 310 is a core device having a thinner gate dielectric 316 (less than 16 A). In one embodiment, the second device 320 is an input/output device having a thicker gate dielectric (greater than 20 A) 386. In one embodiment, the first device 310 operating voltage is less than 1.5 volts, and for the second device 320 it is at least 1.5 volts.

The devices 310 and 320, which are formed on the substrate 301, each include a corresponding active area 305 and 306, such as a p-well or an n-well, and a field oxide region 307 and 308 for isolation. The improved device junction structure for the first and second devices 310 and 320 formed on the substrate 301 includes the first device 310 having a first gate 312 structure having a plurality of first gate layers 314 that are layered upon a first gate dielectric 316. In one embodiment, the first gate dielectric 316 has a thickness that is less than 16 A. In some gate structures, a polysilicon layer (not shown) may also be included. In one embodiment, length of the first gate 312 is less than 40 nm. In one embodiment, thickness of the first gate 312 structure is less than 1000 A.

Pair of first thin spacers 326 is formed on a corresponding sidewall of the first gate 312 structure. First source and first drain regions 330 and 340 are then formed self aligned with and adjacently below on either side of each first thin spacer and a corresponding edge of the first gate 312 structure. In one embodiment, the first source and first drain regions 330 and 340 include impurity concentrations of a selectable type to form a first smooth junction profile 333 under each first thin spacer and the corresponding edge of the first gate 312 structure.

The second device 320 includes a second gate 382 structure having a plurality of second gate layers 384, the plurality of second gate layers being layered upon a second gate dielectric 386. In one embodiment, the second gate dielectric 386 has a thickness that is greater than 20 A. In some gate structures, a polysilicon layer (not shown) may also be included. In one embodiment, length of the second gate 382 is more than 100 nm.

Pair of second thick spacers 366 is formed on a corresponding sidewall of the second gate 382 structure. In one embodiment, a difference between each of the first thin spacers and each of the second thick spacers is selectable to exceed a predefined width. In one embodiment, the predefined width is at least 100 A. Second source and second drain regions 350 and 360 are then formed self aligned with and adjacently below on either side of each second thick spacer and a corresponding edge of the second gate 382 structure. In one embodiment, the second source and second drain regions 350 and 360 include impurity concentrations of a selectable type to form a second smooth junction profile 363 under each second thick spacer and the corresponding edge of the second gate 382 structure.

FIG. 3B is an illustrative layout diagram of first and second devices 310 and 320 each having an improved device junction structure formed on a semiconductor wafer, according to an embodiment. In one embodiment, the first device 310 is a core device (logic portion) and the second device 320 is a SRAM cell. In the depicted embodiment, the layout of the devices is substantially similar to FIG. 3A with exception that the first device 310 includes pair of thick spacers 366 and second device 320 includes pair of thin spacers 326. The SRAM cell includes a CMOS inverter (not shown) and pass gate device (not shown). The CMOS inverter includes a pull down (NMOS) device and a pull up (PMOS) device. In this embodiment, pair of second thick spacers 366 is formed on the sidewalls of the first gate 312 structure and pair of first thin spacers 326 is formed on the sidewalls of the second gate 382 structure. In this embodiment, the thickness of each first thin spacer is less than 25 nm and a difference between the spacer widths, e.g., the predefined width, is at least 50 A.

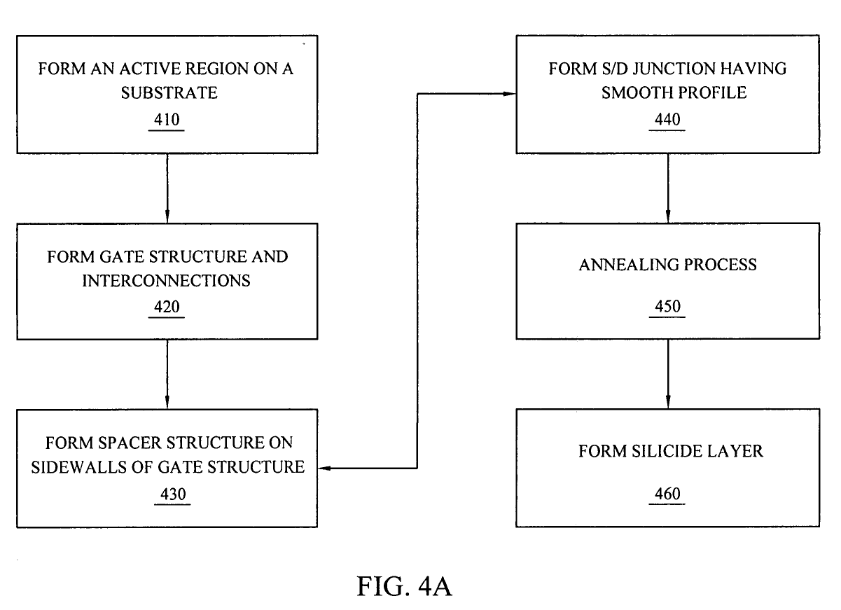

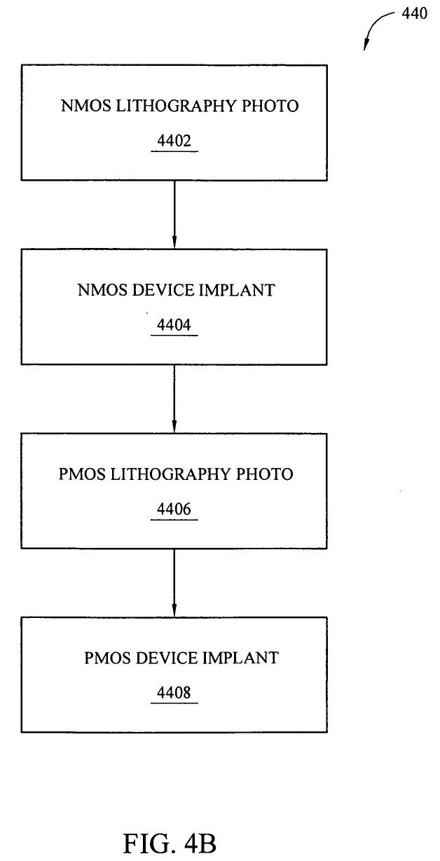

FIG. 4A is an illustrative flowchart of a method for forming a CMOS device on a semiconductor wafer having an improved device junction structure, according to an embodiment. In step 410, an active region such as a N-well or P-well is formed on the substrate. In step 420, a gate structure having various gate layers and interconnections for the MOSFET's are formed. In step 430, spacer structure is formed on the sidewalls of the gate structure. In step 440, core CMOS S/D regions having a smooth profile junction are formed. In step 450, the CMOS device goes through an annealing process. In step 460, a silicide layer is formed to cover the CMOS device.

FIG. 4B is a flowchart illustrating additional details of step 440 to form core CMOS S/D regions, according to an embodiment. Step 440 includes substeps 4402, 4404, 4406 and 4408. Step 4402 includes NMOS lithography photo step and step 4404 includes NMOS device implant step. More specifically, step 4404 for implanting NMOS device includes a) high concentration (larger than 1E15/cm²) but low energy (less than 5 Kev) implant, b) low concentration (less than 5E14/cm²) but high energy (between 30 to 120 Kev) and c) anti-dopant implant steps. The dopant species of high concentration and low concentration include As, P31, Sb or combination thereof. The anti-dopant implant steps include impurity B11, BF2, Indium or a combination thereof; dopant concentrations between 1E13/cm² and 3E14/cm²; and implant energy B11 (500 ev to 5 Kev), BF2 (5 Kev to 40 Kev), Indium (30 Kev to 120 Kev). Step 4406 includes PMOS lithography photo step, which is similar to step 4402 above, and step 4408 includes PMOS device implant step, which is similar to step 4404 above.

Various steps of FIGS. 4A and 4B may be added, omitted, combined, altered, or performed in different orders.

Although the embodiments above have been described in considerable detail, numerous variations and modifications will become apparent to those skilled in the art once the above disclosure is fully appreciated. It is intended that the following claims be interpreted to embrace all such variations and modifications.

What is claimed is:

1. A semiconductor device comprising:
a gate structure having a plurality of gate layers, the plurality of gate layers being layered upon a gate dielectric;
a plurality of thin spacers, wherein each thin spacer is formed on a corresponding sidewall of the gate structure, wherein each thin spacer is at most 25 nanometers (nm) wide; and
source and drain regions, wherein each of the source and drain regions are self aligned and disposed adjacently below on either side of each thin spacer and a corresponding edge of the gate structure, wherein the source and drain regions include impurity concentrations of a selectable type to form a smooth junction profile under each thin spacer and the corresponding edge of the gate structure.

2. The device of claim 1, wherein length of the gate structure is at most 40 nanometers (nm).

3. The device of claim 1, wherein the impurity concentrations of the selectable type include a higher impurity concentration or a lower impurity concentration, wherein the source and drain regions formed by the lower impurity concentration have a deeper depth compared to the higher impurity concentration.

4. The device of claim 3, wherein the deeper depth is at most 35 nm.

5. The device of claim 1, wherein a thickness of the gate dielectric layer is less than 16 angstroms (A).

6. The device of claim 1, wherein a thickness of the gate structure is less than 1000 angstroms (A).

7. The device of claim 1, wherein each thin spacer included in the plurality of thin spacers is formed by a material including silicon oxynitride (SiON), silicon nitride (Si3N4), low pressure tetra-ethoxysilane (LPTEOS), high temperature oxide (HTO), furnace oxide, Hf content oxide, Ta content oxide, Al content oxide, high K dielectric wherein K is greater than 5, oxygen content dielectric, nitrogen content dielectric or a combination thereof.

8. The device of claim 1, wherein the plurality of thin spacers are formed by depositing a thin layer of dielectric material and anisotropically etching the dielectric material along the corresponding sidewall of the gate.

9. A device structure for first and second devices formed on a substrate, the device structure comprising:
a first device including:
a first gate structure having a plurality of first gate layers, the plurality of first gate layers being layered upon a first gate dielectric;
a plurality of first thin spacers, wherein each first thin spacer is formed on a corresponding sidewall of the first gate structure; and
a first source and first drain regions, wherein each of the first source and first drain regions are self aligned and disposed adjacently below on either side of each first thin spacer and a corresponding edge of the first gate structure; and
a second device including:
a second gate structure having a plurality of second gate layers, the plurality of second gate layers being layered upon a second gate dielectric;
a plurality of second thick spacers, wherein each second thick spacer is formed on a corresponding sidewall of the second gate structure, wherein a difference between each of the first thin spacers and each of the second thick spacers is selectable to exceed a predefined width; and
second source and second drain regions, wherein each of the second source and second drain regions are self aligned and disposed adjacently below on either side of each second thick spacer and a corresponding edge of the second gate structure.

10. The device structure of claim 9, wherein a first operating voltage for the first device is less than 1.5 volts, and a second operating voltage for the second device is at least 1.5 volts.

11. The device structure of claim 9, wherein the first source and first drain regions include impurity concentrations of a selectable type to form a smooth junction profile under each first thin spacer and the corresponding edge of the first gate structure.

12. The device structure of claim 9, wherein the second source and second drain regions include impurity concentrations of a selectable type to form a smooth junction profile under each second thick spacer and the corresponding edge of the second gate structure.

13. The device structure of claim 9, wherein a first thickness of the first gate dielectric is less than 16 A and a second thickness of the second gate dielectric is greater than 20 A.

14. The device structure of claim 9, wherein the first device is a core device and the second device is an input/output (I/O) device.

15. The device structure of claim 9, wherein the predefined width is 100 A.

16. A device structure for first and second devices formed on a substrate, the device structure comprising:
a first device including:
a first gate structure having a plurality of first gate layers, the plurality of first gate layers being layered upon a first gate dielectric;
a plurality of first thick spacers, wherein each first thick spacer is formed on a corresponding sidewall of -the first gate structure; and
first source and first drain regions, wherein each of the first source and first drain regions are self aligned and disposed adjacently below on either side of each first thick spacer and a corresponding edge of the first gate structure; and
a second device including:
a second gate structure having a plurality of second gate layers, the plurality of second gate layers being layered upon a second gate dielectric;
a plurality of second thin spacers, wherein each second thin spacer is formed on a corresponding sidewall of the second gate structure, wherein a difference between each of the first thick spacers and each of the second thin spacers is selectable to exceed a predefined width; and
second source and second drain regions, wherein each of the second source and second drain regions are self aligned and disposed adjacently below on either side of each second thin spacer and a corresponding edge of the second gate structure.

17. The device structure of claim 16, wherein the first device is a logic device and the second device is an SRAM device.

18. The device structure of claim 16, wherein the predefined width is 50 A.

19. The device structure of claim 16, wherein a thickness corresponding to each second thin spacer is less than 25 nm.

20. A method for forming a CMOS device on a semiconductor wafer having an improved device junction structure, the method comprising:
forming an active region on a substrate of the wafer;
forming a gate structure having a plurality of gate layers, wherein the plurality of gate layers are layered upon a gate dielectric;
forming a plurality of thin spacers, wherein each thin spacer is formed on a corresponding sidewall of the gate structure, wherein each thin spacer is at most 25 nanometers (nm) wide; and
forming source and drain regions, wherein each of the source and drain regions are self aligned and disposed adjacently below on either side of each thin spacer and a corresponding edge of the gate structure, wherein the source and drain regions include impurity concentrations of a selectable type to form a smooth junction profile under each thin spacer and the corresponding edge of the gate structure;
annealing the device; and
forming a silicide layer to cover the device.

21. The method of claim 20, wherein the impurity concentrations of the selectable type include a higher impurity concentration or a lower impurity concentration, wherein the source and drain regions formed by the lower impurity concentration have a deeper depth compared to the higher impurity concentration.

22. The method of claim 20, wherein the plurality of thin spacers are formed by depositing a thin layer of dielectric material and anisotropically etching the dielectric material along the corresponding sidewall of the gate.
